(19) United States
(12) Patent Application Publication
(10) Pub. No.: US 2026/0106612 A1
(43) Pub. Date: Apr. 16, 2026

(54) SWITCHING TRANSDUCER DRIVER

(71) Applicant: Cirrus Logic International Semiconductor Ltd., Edinburgh (GB)

(72) Inventor: John P. LESSO, Edinburgh (GB)

(73) Assignee: Cirrus Logic International Semiconductor Ltd., Edinburgh (GB)

(21) Appl. No.: 19/340,241

(22) Filed: Sep. 25, 2025

Related U.S. Application Data
(63) Continuation-in-part of application No. 18/948,973, filed on Nov. 15, 2024.
Application No. 18/948,973 is a continuation of application No. 18/308,395, filed on Apr. 27, 2023, now Pat. No. 12,184,272.

(51) Int. Cl. H03K 17/687; H03K 19/00; H03K 19/0185

(52) U.S. Cl. CPC H03K 17/687; H03K 19/0005; H03K 19/018585

(57) ABSTRACT

Switching transducer driver circuitry for driving a load, the switching transducer driver circuitry comprising: output stage circuitry comprising: a first output stage switch operable to couple the load to a first voltage supply; a second output stage switch operable to couple the load to a second voltage supply; and a third output stage switch operable to couple the load to a controllable third voltage supply, wherein a voltage level of the controllable third voltage supply is based on an input signal to the switching amplifier circuitry.

### RELATED APPLICATIONS

This is a continuation-in-part of U.S. patent application Ser. No. 18/948,973, filed on 27 Apr. 2023.

### FIELD OF THE INVENTION

The present disclosure relates to a switching transducer driver.

### BACKGROUND

Switching transducer drivers such as Class D amplifiers are increasingly being used in electronic devices for which power efficiency is important, such as mobile telephones, portable media players, laptop and tablet computers, wireless headphones, earphones and earbuds. Such transducer drivers are also increasingly finding use in automotive applications, e.g. in vehicle audio systems and the like.

A typical switching transducer driver (e.g. a Class D amplifier) includes a modulator stage and an output stage. In low-power applications such as portable audio devices it is common for the output stage to be implemented as a full-bridge output stage, with a load such as a speaker being coupled in a bridge-tied load configuration between first and second half bridges.

FIG. 1 is a schematic representation of a full bridge output stage 100 comprising a first half-bridge 110 and a second half-bridge 120, which together provide a differential output voltage Vout for driving a bridge-tied load 130 (e.g. a loudspeaker) that can be coupled between respective output nodes 112, 122 of the first and second half-bridges 110, 120.

The first half-bridge 110 comprises a high-side switch 114 coupled in series with a low-side switch 116 between a first supply voltage (VDD) rail 142 and a reference voltage (e.g. ground) rail 144 of the output stage 100. The high-side switch 114 and the low-side switch 116 may be, for example, MOSFET devices.

Similarly, the second half-bridge 120 comprises a high-side switch 124 coupled in series with a low-side switch 126 between the first supply voltage (VDD) rail 142 and the reference voltage (e.g. ground) rail 144 of the output stage 100. Again, the high-side switch 124 and the low-side switch 126 may be, for example, MOSFET devices.

In use of the output stage 100, control signals such as pulse width modulated (PWM) signals are supplied to control terminals (e.g. gate terminals) of the high-side switch 114 and low-side switch 116 of the first half-bridge 110, and to control terminals (e.g. gate terminals) of the high-side switch 124 and the low-side switch 126 of the second half-bridge 120. The control signals are arranged such that when the high-side switch 114 is switched on in response to a control signal at its control terminal, the low-side switch 116 is switched off, and vice versa. Thus, in operation of the first half-bridge 110, the output node 112 will be at either the first supply voltage (VDD) or the reference voltage (e.g. ground), depending upon whether the high-side switch 114 or the low-side switch 116 is switched on. Similarly, in operation of the second half-bridge 120, the output node 122 will be at either the first supply voltage (VDD) or the reference voltage (e.g. ground), depending upon whether the high-side switch 124 or the low-side switch 126 is switched on. The output voltage Vout across the load 130 can thus take any of three levels: +VDD, −VDD or 0V (assuming that the reference voltage rail 144 is coupled to ground).

In some low-power applications the output stage 100 may be implemented in integrated circuitry (e.g. in a single integrated circuit) comprising the switches 114, 116, 124, 126. In some examples, such integrated circuitry may also comprise modulator circuitry for supplying the control signals to the switches 114, 116, 124, 126 of the output stage 100.

In higher power applications (e.g. automotive audio applications) it may be beneficial to use a single-ended output stage of the kind shown schematically in FIG. 2.

As shown in FIG. 2, the single-ended output stage 200 in this example comprises a half-bridge 210 having a high-side switch 212 coupled in series with a low-side switch 214 between a first, positive (+VDD) supply voltage rail 222 and a second, negative (−VDD) supply voltage rail 224 of the single-ended output stage 200. The high-side switch 212 and the low-side switch 214 may be, for example, MOSFET devices.

In use of the single-ended output stage 200, a load 230 such as a loudspeaker is coupled between an output node 216 of the half-bridge 210 and a reference voltage (e.g. ground) rail 226 of the single-ended output stage 200. In the example shown in FIG. 2 low-pass filter circuitry 240 comprising an inductor 242 and a capacitor 244 is coupled between the output node 216 and the load 230, to attenuate high frequency components that may be present in an output signal of the half-bridge 210 due to the switching frequency of the switches 212, 214.

Unlike the full bridge output stage 100 of FIG. 1, the single-ended output stage 200 of FIG. 2 requires a negative (−VDD) supply voltage rail 224. As will be appreciated by those skilled in the art, this may increase the complexity of the single-ended output stage 200, as compared to the full bridge output stage 100 of FIG. 1. However, the single-ended output stage 200 may be more cost effective than the full bridge output stage 100. In particular, where multiple channels are required (e.g. in an application such as a multi-channel audio system where multiple different loads such as loudspeakers are to be driven) it may be more cost effective to use one single-ended output stage of the kind shown in FIG. 2 per channel, with the negative (−VDD) supply voltage rail 224 being shared between all the channels, than to provide multiple full bridge output stages.

In operation of the single-ended output stage 200, control signals (e.g. PWM signals) are supplied to control terminals (e.g. gate terminals) of the high-side switch 212 and low-side switch 214 of the half-bridge 210. The control signals are arranged such that when the high-side switch 212 is switched on in response to a control signal at its control terminal, the low-side switch 214 is switched off, and vice versa. Thus, in operation of the half-bridge 210, the output node 216 will be at either the first supply voltage (+VDD) or the second supply voltage (−VDD), depending upon whether the high-side switch 212 or the low-side switch 214 is switched on. The output voltage Vout across the load 230 can thus take one of two levels: +VDD or −VDD.

In some examples the single-ended output stage 200 may be implemented in integrated circuitry (e.g. as a single integrated circuit incorporating the high-side switch 212 and the low-side switch 214, and perhaps also modulator circuitry for generating the control signals that are supplied to the switches 212, 214), but the low-pass filter circuitry 240 is typically implemented using discrete components that are not implemented in integrated circuitry—i.e. the inductor 242 and capacitor 244 of the low-pass filter circuitry 240 are typically off-chip devices. However, in other examples the single-ended output stage 200 may be implemented entirely using off-chip devices, particularly in high-power applications where the cost of on-chip switches may be greater than that of off-chip switches.

A disadvantage of the single-ended output stage 200 of FIG. 2 is that a ripple current flows through the load 230, because the repeated switching of the output voltage Vout between +VDD and −VDD gives rise to a varying current through the inductor 242 of the low-pass filter circuitry 240, which manifests as ripple current through the load 230. This load ripple current can lead to power (12R) losses which can be significant, particularly in higher power use cases such as automotive applications.

### SUMMARY

According to a first aspect, the invention provides switching transducer driver circuitry for driving a load, the switching transducer driver circuitry comprising: output stage circuitry comprising: a first output stage switch operable to couple the load to a first voltage supply; a second output stage switch operable to couple the load to a second voltage supply; and a third output stage switch operable to couple the load to a controllable third voltage supply, wherein a voltage level of the controllable third voltage supply is based on an input signal to the switching amplifier circuitry.

The switching transducer driver circuitry may further comprise DC-DC converter circuitry configured to provide the controllable third voltage supply.

The switching transducer driver circuitry may further comprise monitor circuitry configured to: monitor a parameter of the input signal; determine a desired voltage level of the controllable third voltage supply based on the monitored parameter of the input signal; and output a signal indicative of the desired voltage level of the controllable third voltage supply to DC-DC converter circuitry coupled to the switching transducer driver circuitry.

The monitor circuitry may be configured to monitor one or more of: an instantaneous magnitude of the input signal; an envelope of the input signal; and a volume control signal associated with the input signal.

The output stage circuitry may comprise control circuitry for controlling operation of the first, second and third output stage switches based on the input signal and the voltage level of the controllable third voltage supply.

The control circuitry may be configured to detect the voltage level of the controllable third voltage supply.

The output stage circuitry may comprise control circuitry for controlling operation of the first, second and third output stage switches based on the input signal and the voltage level of the controllable third voltage supply. The monitor circuitry may be configured to output a signal indicative of the desired voltage level of the controllable third voltage supply to the control circuitry.

A maximum voltage level of the controllable third voltage supply may be equal to a mid-point voltage level between a level of the first supply voltage and a level of the second supply voltage.

The monitor circuitry may be configured to determine the desired voltage level of the controllable third voltage supply for a given magnitude A of an output signal of the switching transducer driver circuitry as a minimum of the magnitude A of the output signal and a mid-point voltage level between a level of the first supply voltage and a level of the second supply voltage.

The monitor circuitry may be configured to determine the desired level of the controllable third voltage supply for a given magnitude A of an output signal of the switching transducer driver circuitry as: the magnitude A of the output signal, if A is equal to or less than a predefined output signal magnitude threshold; or (0.5+0.5√(A/V)), if A is greater than the predefined output signal magnitude threshold, where V is equal to a difference between a level of the first voltage supply and a level of the second voltage supply.

The first and second output stage switches may be implemented using wide bandgap or high electron mobility transistor (HEMT) devices.

The third output stage switch may be implemented using a wide bandgap or high electron mobility transistor (HEMT) device.

The DC-DC converter circuitry may comprise zeta buck converter circuitry.

According to a second aspect, the invention provides a combined output stage and DC-DC converter integrated circuit (IC), the combined output stage and DC-DC converter IC comprising: a switch network for a DC-DC converter; a first output stage switch operable to couple a load to a first voltage supply; a second output stage switch operable to couple the load to a second voltage supply; and a third output stage switch operable to couple the load to a controllable third voltage supply, wherein the controllable third voltage supply is supplied by the DC-DC converter.

The combined output stage and DC-DC converter IC may further comprise an inductor for the DC-DC converter.

The first and second output stage switches and switches of the switch network for the DC-DC converter may be implemented using wide bandgap or high electron mobility transistor (HEMT) devices.

The third output stage switch may be implemented using a wide bandgap or high electron mobility transistor (HEMT) device.

According to a third aspect, the invention provides a host device comprising the switching transducer driver circuitry of the first aspect of the combined output stage and DC-DC converter IC of the second aspect.

The host device may comprise a vehicle, a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console, a VR or AR device, a mobile telephone, a portable audio player or other portable device.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1 is a schematic representation of a full-bridge output stage for use as a Class D amplifier output stage;

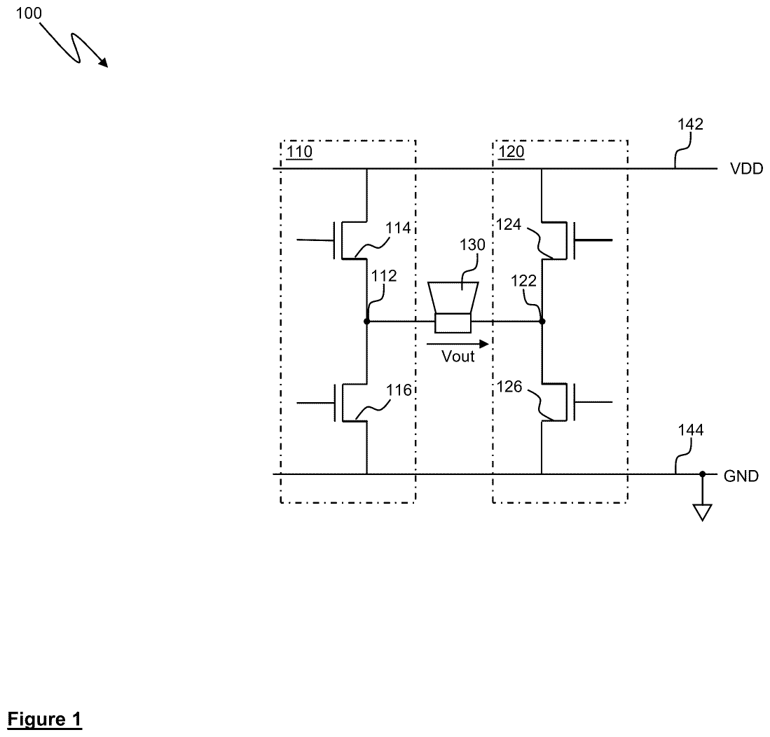

FIG. 2 is a schematic representation of a half-bridge output stage for use as a Class D amplifier output stage;

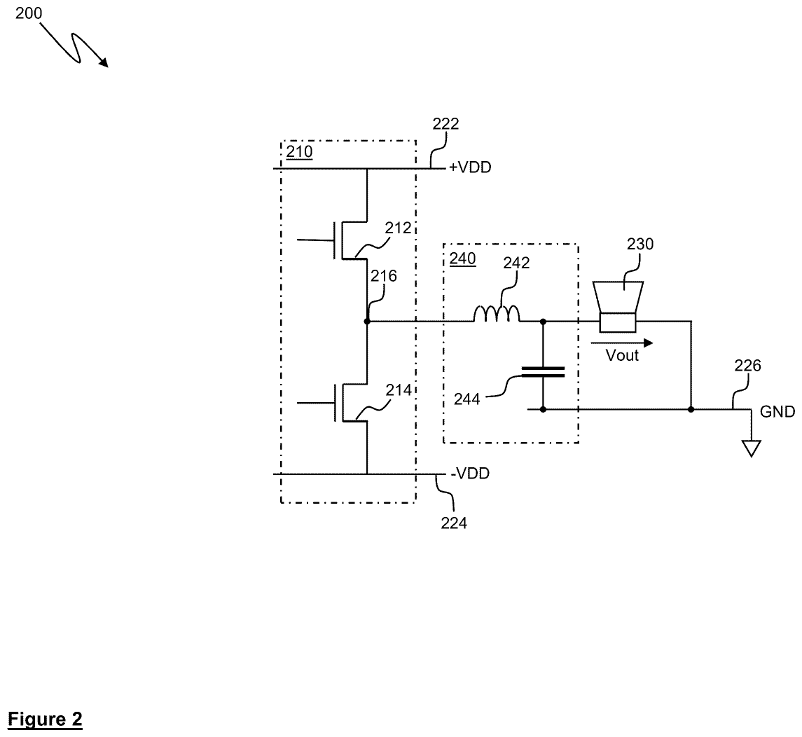

FIG. 3 is a schematic representation of switching transducer driver circuitry according to the present disclosure

FIG. 4 is a schematic representation of control circuitry for supplying control signals for the switching transducer driver of FIG. 3;

FIG. 5 shows the effect of different values of a variable a on an output signal of modulator circuitry of the control circuitry of FIG. 4;

FIGS. 6a and 6b illustrate different approaches to switching between operating modes of the switching transducer driver of FIG. 3; and

FIG. 7 is a schematic representation of a back-to-back switch arrangement that may be used in the switching transducer driver of FIG. 3;

FIG. 8 is a schematic representation of another example of switching transducer driver circuitry according to the present disclosure;

FIG. 9 is a schematic representation of an implementation of the switching transducer driver circuitry of FIG. 8 having a full-bridge output stage; and

FIG. 10 is a schematic representation of an implementation of the switching transducer driver circuitry of FIG. 8 having a half-bridge output stage.

### DETAILED DESCRIPTION

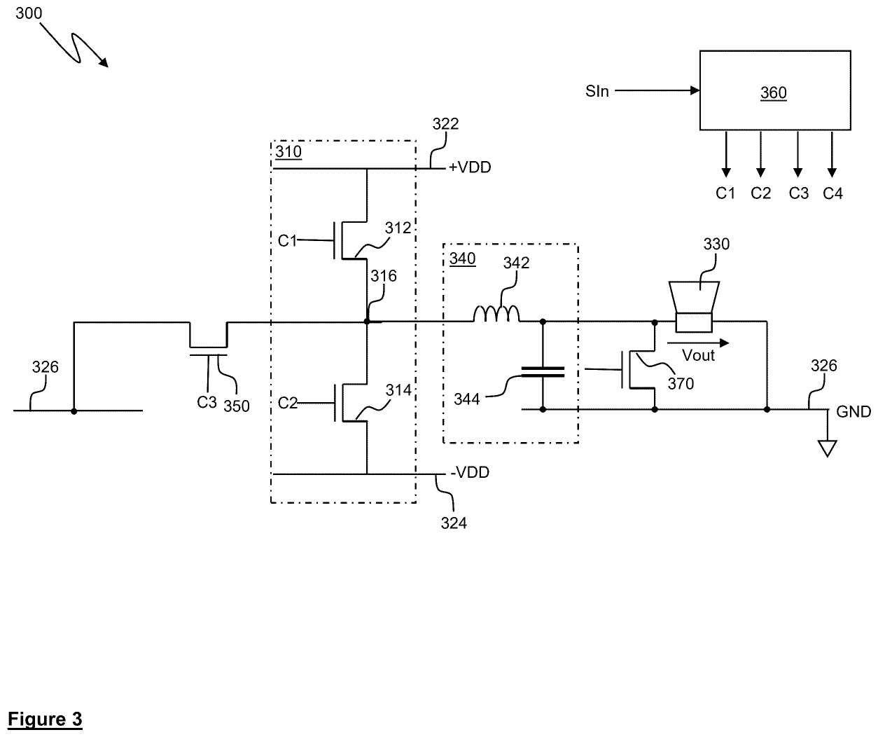

FIG. 3 is a schematic representation of switching transducer driver circuitry according to the present disclosure.

The switching transducer driver in this example is implemented as Class D amplifier circuitry, which is shown generally at 300 in FIG. 3. The Class D amplifier circuitry 300 comprises a half-bridge 310 comprising a high-side switch 312 and a low-side switch 314 coupled in series between a first, positive (+VDD) power supply rail 322 and a second, negative (−VDD) power supply rail 324, with an output node 316 of the half-bridge 310 being coupled, via low-pass filter circuitry 340 (which comprises an inductor 342 and a capacitor 344) to a first terminal of a load 330, the load having a second terminal coupled to a reference voltage (e.g. ground) rail 326.

The Class D amplifier circuitry 300 of FIG. 3 further comprises a third switch 350, having an input terminal coupled to the reference voltage (e.g. ground) rail 326 and an output terminal coupled to the output node 316 of the half-bridge 310.

The Class D amplifier circuitry 300 further comprises control circuitry 360 configured to control a mode of operation of the Class D amplifier circuitry 300. In some examples, the control circuitry 360 may control the mode of operation of the Class D amplifier circuitry 300 based on a parameter such as a signal level, magnitude, envelope or volume of an input signal.

The Class D amplifier circuitry 300 of FIG. 3 is configured for operation with relatively high output power. For example, the positive power supply voltage +VDD and the negative power supply voltage-VDD may each have a magnitude of 50V DC or more. The high-side switch 312 and the low-side switch 314 are thus configured for operation at such voltages. In some examples the high-side switch 312 and the low-side switch 314 may be wide bandgap devices or high electron mobility transistor (HEMT) devices based on, for example, Gallium Nitride (GaN), Silicon Carbide (SIC), Gallium Oxide (Ga₂0₃) or other semiconductor materials. Such devices are typically capable of operation at higher voltages, higher temperatures and higher frequencies than silicon-based switches such as MOSFETs, and so for high power applications (e.g. applications in which the supply voltage magnitude is equal to or greater than 50V DC) may provide a more cost effective solution than silicon-based devices. The circuit area occupied by the switches 312, 314 in a switching transducer driver of the kind shown in FIG. 3 may be minimised or at least reduced by using switches having higher resistance, but as the resistance of the switches increases the supply voltage also increases. For example, if the resistance of the switches 312, 314 were doubled, the required supply voltage would also double. This trade-off between switch size and supply voltage is manageable and acceptable if the switches 312, 314 are implemented as GaN devices.

In use of the Class D amplifier circuitry 300, control signals C1, C2, C3 are supplied by the control circuitry 360 to control terminals of the high-side switch 312, the low-side switch 314 and the third switch 350 respectively. The control signals C1, C2, C3 are arranged such that only one of the high-side switch 312, the low-side switch 314 and the third switch 350 can be switched on at once, so the output voltage Vout across the load 330 may take one of three values: +VDD (when the high-side switch 312 is switched on and the low-side switch 314 and the third switch 350 are both switched off), −VDD (when the low-side switch 314 is switched on and the high-side switch 312 and the third switch 350 are both switched off), or 0V (when the high-side switch 312 and the low-side switch 314 are both switched off and the third switch 350 is switched on). These three output voltage values may be used to encode three different values. For example, an output voltage of +VDD may represent a value of +1, an output voltage of −VDD may represent a value of −1 and an output voltage of 0 may represent a value of 0.

The Class D amplifier circuitry 300 is thus capable of operating in a first mode with two output voltage levels, if the third switch 350 is held open (i.e. switched off). The Class D amplifier circuitry 300 can also operate in a second mode with three output voltage levels. In applications such as audio amplification, at high input signal levels (e.g. high-volume audio signals) only the +VDD and −VDD output voltages may be required, because at high input signal levels there will be relatively few input signal states that require the 0V output stage. In contrast, at lower input signal levels (e.g. lower volume audio signals) the 0V output voltage may also be required, because at low input signal levels there will be more input signal states that required the 0V output stage.

Thus, the control circuitry 360 may be operative to control a mode of operation of the Class D amplifier circuitry 300 based on a level of an input signal level SIn. If a parameter (e.g. a level, a magnitude, an envelope, a volume or some other property or parameter of the input signal) of the input signal is equal to or greater than a threshold, the control circuitry 360 may be operative to generate control signals C1, C2, C3 to cause the Class D amplifier circuitry 300 to operate in its first mode with two output signal levels. In this case, the control signal C3 supplied to the third switch 350 causes the third switch 350 to be held in an open or off state, to prevent the output node 316 from being coupled to the reference voltage (e.g. ground) rail 326 and thus prevent the 0V output state from being achievable. In contrast, if the parameter of the input signal is below the threshold, the control circuitry 360 may be operative to generate control signals C1, C2, C3 to cause the Class D amplifier circuitry 300 to operate in its second mode, with three output signal levels.

The control circuitry 360 may comprise pulse width modulator circuitry for generating a PWM signal S based on an input signal and one or more carrier wave signals. The control circuitry 360 may further comprise logic circuitry for generating the control signals C1, C2, C3 from the PWM signal generated by the pulse width modulator circuitry.

An advantage of operating in the first mode with only two output signal levels is increased linearity, in comparison to operating in the second mode with three output signal levels. Switching between two different voltages is inherently linear, but switching between three may require matching of components to produce linearized output. This is of particular significance when the switches 312, 314 are off-chip, and when a modulator/amplifier (e.g. the PWM modulator circuitry of the control circuitry 360) is operating in open-loop mode.

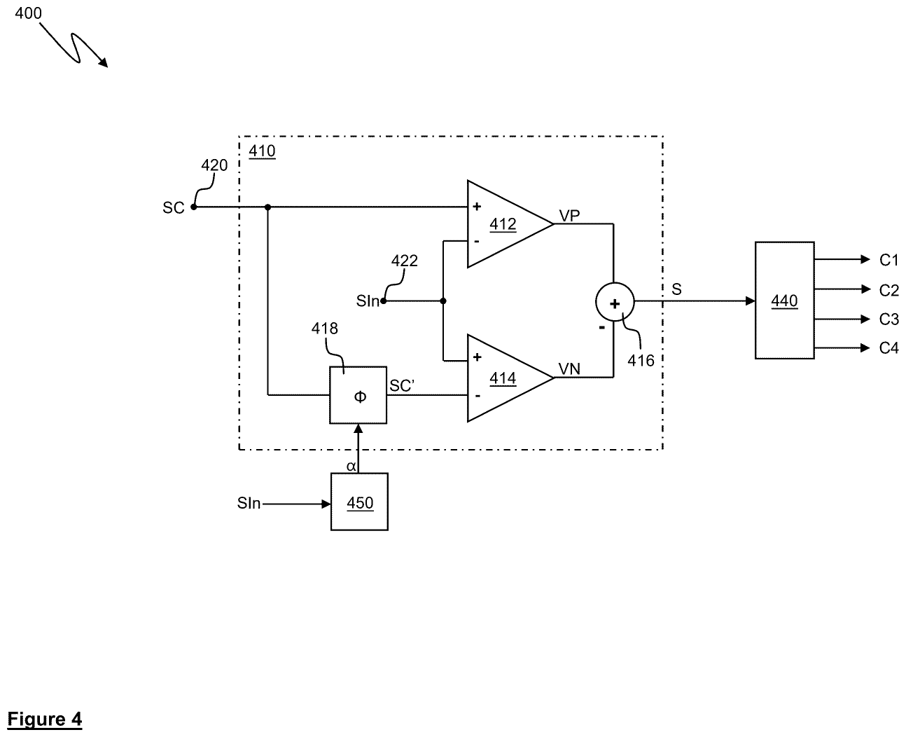

FIG. 4 is a schematic representation of control circuitry for the Class D amplifier circuitry 300 of FIG. 3. As shown generally at 400 in FIG. 4, the control circuitry in this example includes open-loop PWM modulator circuitry 410, logic circuitry 440 and phase shift control circuitry 450.

The PWM modulator circuitry 410 in this example includes first and second comparators 412, 414, a subtractor 416 and a variable phase shift element 418. An input of the variable phase shift element 418 is coupled to a carrier wave input node 420 of the PWM modulator circuitry 410, and an output of the variable phase shift element 418 is coupled to an inverting (−) input of the second comparator 414. The carrier wave input node 420 is also coupled to a non-inverting (+) input of the first comparator 412. An input signal node 422 is coupled to an inverting (−) input of the first comparator 412 and to a non-inverting (+) input of the second comparator 414. Outputs of the first and second comparators 412, 414 are coupled to respective first and second inputs of the subtractor 416. An output of the subtractor 416 is coupled to an input of the logic circuitry 440.

In use of the control circuitry 400, a carrier wave signal SC, which may be, for example, a triangle wave signal, a sawtooth wave signal or some other cyclical reference signal, is supplied to the carrier wave input node 420 of the PWM modulator circuitry 410 and is thus transmitted to the non-inverting (+) input of the first comparator 412 and to the input of the variable phase shift element 418.

The variable phase shift element 418 is configured to apply a phase shift φ of between 0 and π (i.e. between 0 and 180°) to the carrier wave signal SC received at its input, and to output a phase shifted version SC′ of the carrier wave signal SC to the inverting (−) input of the second comparator 414. As will be appreciated by those of ordinary skill in the art, the variable phase shift element 418 may be implemented in a variety of ways. For example, the variable phase shift element 418 may be implemented by programmable delay circuitry, all-pass filter circuitry with a variable phase, unity gain amplifier circuitry with a variable phase, or the like.

The phase shift φ applied by the variable phase shift element 418 can be defined as φ=α. π, where α is a variable having a value between 0 and 1 that is dependent upon a parameter of an input signal SIn. For example, a may be dependent upon a magnitude, level, envelope or volume of the input signal SIn, such that the phase shift φ applied by the variable phase shift element is dependent on the magnitude, level, envelope or volume of the input signal SIn. The variable phase shift element 418 receives, from the phase shift control circuitry 450, a control signal indicative of the value a and controls or adjusts the phase shift φ applied to the received carrier wave signal SC based on this received control signal.

The input signal SIn, which may be, for example, an audio input signal, is supplied to the input signal node 422 and is thus transmitted to the inverting (−) input of the first comparator 412 and to the non-inverting (+) input of the second comparator 414.

The first comparator 412 thus generates a first comparator output signal VP based on a comparison of the input signal SIn to the carrier wave signal SC, where the first comparator output signal VP takes a high value (e.g. logic 1) if the magnitude of the carrier wave signal SC is greater than that of the input signal SIn, and the first comparator output signal VP takes a low value (e.g. logic 0) if the magnitude of the carrier wave signal SC is less than that of the input signal SIN. This can be expressed as VP=SC−SIn>0.

Similarly, the second comparator 414 generates a second comparator output signal VN based on a comparison of the input signal SIn to the phase shifted version SC′ of the carrier wave signal SC, where the second comparator output signal VN takes a high value (e.g. logic 1) if the magnitude of the input signal SIn is greater than that of the phase shifted version SC′ of the carrier wave signal SC, and the second comparator output signal VN takes a low value (e.g. logic 0) if the magnitude of the input signal SIn is less than that of the phase shifted version SC′ of the carrier wave signal. This can be expressed as VN=SIn−SCe^{-iφ}>0.

The subtractor 416 subtracts the second comparator output signal VN from the first comparator output signal VP to generate the PWM output signal S, such that S=VP−VN.

The PWM output signal S is received by the logic circuitry 440, which is configured to generate the control signals C1, C2, C3 for the switches 312, 314, 350 of the Class D amplifier circuitry 300 based on the received PWM output signal S.

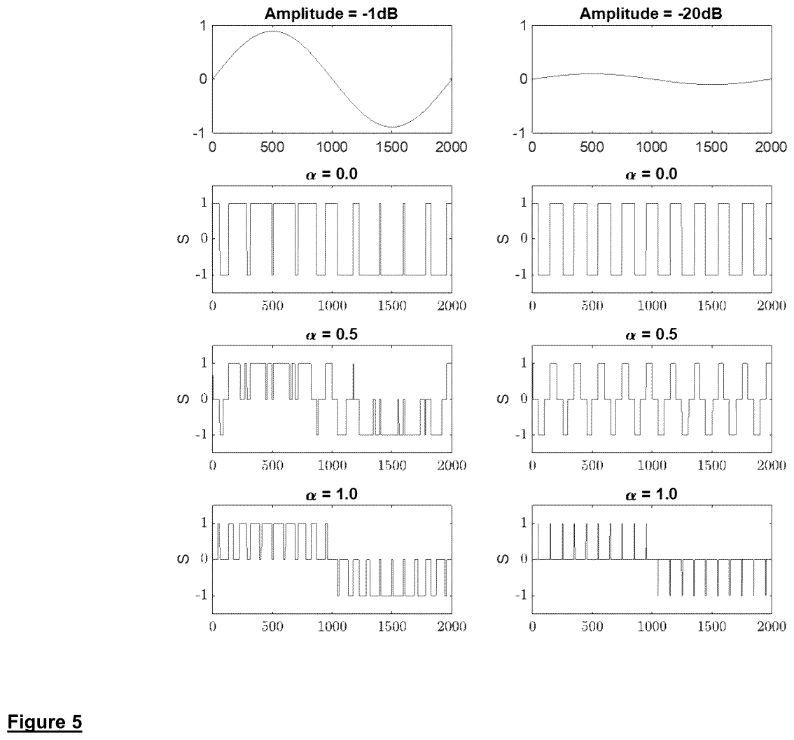

FIG. 5 shows the effect of different values of a on the output signal S. As will be apparent from the signal traces shown in FIG. 5, when a is equal to 0, the PWM output signal S can adopt one of two states (i.e. the modulator circuitry 410 operates as a two-level modulator), shown as +1 and −1 in FIG. 5. Thus, when a is equal to 0, the Class D amplifier circuitry 300 operates in its first mode, in which the output signal supplied to the load 330 can take one of two levels, based on a state (on/off) of each of the high-side switch 312 and the low-side switch 314.

In contrast, when a is greater than 0, the PWM output signal S can adopt any one of three states (i.e. the modulator circuitry 410 operates as a three-level modulator), shown as +1, −1 and 0 in FIG. 5, with the occurrence of the 0 state being more frequent for higher values of a. Thus, when a greater than 0, the Class D amplifier circuitry 300 operates in its second mode, in which the output signal supplied to the load 330 can take one of three levels, based on a state (on/off) of each of the high-side switch 312, the low-side switch 314 and the third switch 350.

The logic circuitry 440 is configured to generate the control signals C1, C2, C3 for the switches 312, 314, 350 of the Class D amplifier circuitry 300 based on the received PWM output signal S. For example, the logic circuitry 440 may be configured to output a control signal C1 that will cause the high-side switch 312 to switch on and to output control signals C2 and C3 that will cause the low-side switch 314 and the third switch 350 to switch off when the PWM output signal S adopts a first state (e.g. the +1 state shown in FIG. 5), to output a control signal C2 that will cause the low-side switch 314 to switch on and to output control signals C1 and C3 that will cause the high-side switch 312 and the third switch 350 to switch off when the PWM output signal S adopts a second state (e.g. the −1 state shown in FIG. 5), and to output a control signal C3 that will cause the third switch 350 to switch on and to output control signals C1 and C2 that will cause the high-side switch 312 and the low-side switch 314 to switch off when the PWM output signal S adopts a third state (e.g. the 0 state shown in FIG. 5).

As noted above, for input signals of relatively large magnitude, the 0 state of the PWM output signal S is typically not required. Thus, the phase shift φ may be set to 0 for such input signals. Conversely, for input signals of relatively lower magnitude, the 0 state of the PWM output signal may be required to a greater or lesser extent depending on the magnitude of the input signal. Thus, the phase shift φ may be set to be greater than 0 for such input signals.

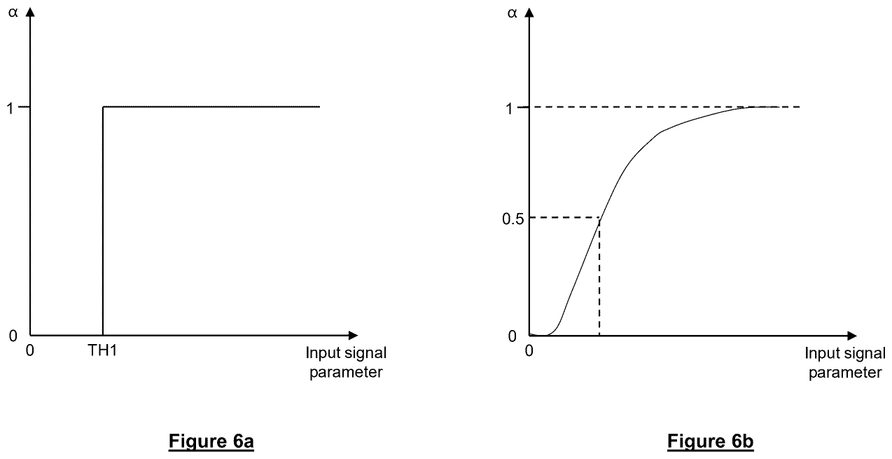

To this end, the phase shift control circuitry 450 is configured to generate the control signal indicative of the value a based on a parameter such as a magnitude, level, envelope or volume of the input signal SIn. In some examples the phase shift control circuitry 450 is configured to compare the parameter of the input signal SIn to a first predefined threshold parameter value TH1 and to change the value a from 0 to 1 if the parameter of the input signal SIn is equal to or greater than the first predefined threshold parameter value TH1, as shown in FIG. 6a. In other examples the phase shift control circuitry 450 is configured to monitor the parameter of the input signal and adjust the value a over a continuous range between 0 and an upper limit value (e.g. 1) as a function of the parameter of the input signal, as illustrated in FIG. 6b. In both of these examples the phase shift control circuitry 450 is configured to determine the value a based on the parameter of the input signal SIn and to generate the control signal indicative of the value a for output to the variable phase shift element 418. In some examples it may be advantageous for the upper limit value of α to be less than 1 (e.g. the value a may be adjustable over a range between 0 and 0.8, 0.9 or some other upper limit value that is less than 1) to ensure that the phase shift φ cannot be π (180°), to prevent small pulses in the output signal S output by the modulator circuitry 410.

The point or threshold at which the modulator circuitry 410 should switch between two-level modulation and three level modulation of the input signal SIn is a function of the on-resistance of the third switch 350. This point or threshold should be selected to balance reducing ripple current through the load 330 (and the attendant distortion in the output of the load 330) and thus power consumption by the load due to resistive (I²R) losses in the load 330 with increased power consumption due to increased resistive (I²R) losses that may arise when the third switch 350 is used to provide the 0 state in the PWM output signal S, so as to achieve an overall reduction in the power consumption of the Class D amplifier circuitry 300.

In some examples, the Class D amplifier circuitry 300 may be operable in a third mode, in which the input of the Class D amplifier circuitry 300 (and possibly also the output of the Class D amplifier circuitry 300) is clamped to the reference voltage (e.g. ground) rail 326 or to some other reference voltage source. The third mode may be entered when a parameter of the input signal (e.g. a magnitude, signal level, envelope or volume) of the input signal SIn is less than a second predefined threshold parameter value TH2, indicating that the input signal SIn does not represent a signal to be amplified. Thus, when the parameter of the input signal Sin is less than the second predefined threshold parameter value TH2, the control circuitry 360 may output a control signal C3 to the third switch 350 to cause it to close, thus clamping the input of the Class D amplifier circuitry 300 to the reference voltage (e.g. ground) rail 326.

In some examples, the output of the Class D amplifier circuitry 300 may be clamped to the reference voltage (e.g. ground) rail 326 or to some other reference voltage source in the third mode of operation, in addition to or instead of clamping the input of the Class D amplifier circuitry 300. To this end, the Class D amplifier circuitry 300 may include a fourth switch 370 coupled between the output of the low-pass filter circuitry 340 and the reference voltage (e.g. ground) rail 326. When the parameter of the input signal SIn is less than the second predefined threshold parameter value TH2, the control circuitry 360 may output a control signal C4 to the fourth switch 370 to cause it to close, thereby clamping the output of the Class D amplifier circuitry 360 to the reference voltage (e.g. ground) rail 326.

In some examples, the Class D amplifier circuitry 300 may be operable only in the above-described first and third modes. In such examples, the first mode may be referred to as an active mode and the third mode may be referred to as a quiescent mode. In such examples, the control circuitry 360 may be operative to control the mode of operation of the Class D amplifier circuitry 300 based on a parameter of the input signal SIn. If a parameter (e.g. a level, a magnitude, an envelope, a volume or some other property or parameter) of the input signal SIn is equal to or greater than a threshold, the control circuitry 360 may be operative to generate control signals C1, C2, C3 to cause the Class D amplifier circuitry 300 to operate in its first (active) mode with two output signal levels. In this case, the control signal C3 supplied to the third switch 350 causes the third switch 350 to be held in an open or off state, to prevent the output node 316 from being coupled to the reference voltage (e.g. ground) rail 326 and thus prevent the 0V output state from being achievable. In contrast, if the parameter of the input signal is below the threshold, the control circuitry 360 may be operative to generate a control signal C4 to cause the Class D amplifier circuitry 300 to operate in its third (quiescent) mode, with the output of the Class D amplifier circuitry 300 clamped to the reference voltage (e.g. ground) rail 326 by closing the fourth switch 370. The control circuitry 360 may be operative to generate a control signal C3 to cause the input of the Class D amplifier circuitry 300 also to be clamped to the reference voltage (e.g. ground) rail 326 in this mode.

In a practical implementation of the Class D amplifier circuitry 300 of FIG. 3, the high-side switch 312, the low-side switch 314 and the third switch 350 may be of the same device type or technology, but a characteristic of the third switch 350 may be inferior to a corresponding characteristic of the high-side switch 312 and the low-side switch 314 to minimise or at least reduce cost, in comparison to using devices having the same characteristics for each of the high-side switch 312, the low-side switch 314 and the third switch 350.

For example, to minimise or reduce the cost of the Class D amplifier circuitry 300, the high-side switch 312 and the low-side switch 314 may be implemented using wide bandgap or HEMT devices having an impedance (e.g. an on-resistance such as a drain-to-source resistance Rds) of the order of a few milliohms or tens of milliohms, whereas the third switch 350 may be implemented using a lower cost wide bandgap or

HEMT device having a greater on-resistance of the order of tens or hundreds of milliohms. The on-resistance of the third switch 350 may be at least twice, and may be significantly more than twice, the on-resistance of the high-side switch 312 and the low-side switch 314. As an illustrative example, the on-resistance of the high-side switch 312 and the low-side switch may be of the order of 70 milliohms, whereas the on-resistance of the third switch 350 may be of the order of 140 milliohms or greater, e.g. 500 milliohms.

In such implementations of the Class D amplifier circuitry 300, the threshold at which the modulator circuitry 410 switches between two-level modulation and three level modulation should be selected such that the benefit of reduced output ripple current at low input signal levels outweighs the disadvantage of increased power consumption that arises as a result of the use of the third switch 350 (and its greater on-resistance) to provide the 0 state in the PWM output signal S at lower signal levels.

In other examples, the third switch 350 may be of a different device type or technology than the high-side switch 312 and the low-side switch 314. For example, the high-side switch 312 and the low-side switch 314 may be implemented using wide bandgap or HEMT devices (e.g. GaN-based devices), while the third switch 350 may be implemented using one or more MOSFET devices or one or more wide-bandgap or HEMT devices based on a different semiconductor material, e.g. SiN. In such examples, the threshold at which the modulator circuitry 410 switches between two-level modulation and three level modulation should again be selected to balance the benefit of reduced output ripple current at low input signal levels against the disadvantage of increased power consumption at low input signal levels.

Further, in such examples, the impedance (e.g. on-resistance) of the third switch 350 may not differ significantly from the corresponding impedance (e.g. on-resistance) of the high-side switch 312 and the low-side switch 314, but the third switch 350 may have a lower (perhaps significantly lower) maximum switching speed than the high-side switch 312 and the low side-switch 314. Thus, in such examples it may be beneficial to reduce a switching frequency, speed or edge rate of the control circuitry 360 when switching to three-level modulation, as the maximum switching speed that can be supported by the high-side switch 312 and low-side switch 314 may be greater than the maximum switching speed that can be supported by the third switch 350. Thus, reducing the switching speed or edge rate of the control circuitry 360 ensures that the control signals C1, C2, C3 output by the control circuitry 360 are at a switching speed or edge rate that can be accommodated by all the switches 312, 314, 350. For example, when operating in the first (two-level modulation) mode, the switching frequency, speed or edge rate may be of the order of 1 MHz or more, whereas when operating in the second (three-level modulation) mode, the switching frequency, speed or edge rate may be of the order of 100 KHz.

In some examples, particularly for low power applications, the high-side switch 312, low-side switch 314 and third switch may all be implemented using MOSFET devices. In such examples, the Class D amplifier circuitry 300 may be implemented in a single integrated circuit. The control circuitry 360 may also be implemented in the same integrated circuit as the Class D amplifier in such examples. In examples where only the third switch 350 is implemented using a MOSFET device, the third switch 350 may be implemented in integrated circuitry, e.g. in a single integrated circuit that may also implement the control circuitry 360.

The present disclosure thus extends to an integrated circuit comprising control circuitry of the kind described herein for supplying control signals to the high-side switch 312, low-side switch 314 and the third switch 350, where the control circuitry is operable to select between the above-described first and second modes of operation and/or between the above-described first and third modes of operation. The integrated circuit may include driver circuitry for driving control terminals (e.g. gate terminals) of the high-side switch 312 and the low-side switch 314. Additionally or alternatively, the integrated circuit may include the third switch 350.

The present disclosure extends to a module comprising a substrate such as a printed circuit board (PCB) or the like on which the third switch 350 (when implemented using a MOSFET device, either in discrete circuitry or integrated circuitry), the high-side switch 312 and the low-side switch 314 are mounted and coupled with suitable connecting circuitry such as conductive tracks or traces.

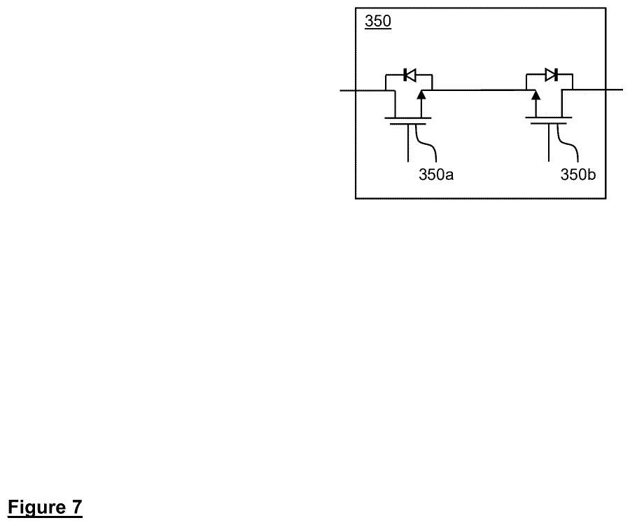

In the example illustrated in FIG. 3, the third switch 350 is shown as a single switch. However, in some examples the third switch may be implemented as two back-to-back coupled switches, as shown in FIG. 7, to prevent reverse current flow through a body diode of the third switch 350 when the third switch 350 is switched off. Thus, the third switch 350 may be implemented by a combination of a first MOSFET device 350a and a second MOSFET device 350b, with source terminals of the first and second MOSFET devices 350a, 350b being coupled together such that, in the illustrated example, an anode of a body diode of the first MOSFET device 350a is coupled to an anode of a body diode of the second MOSFET device 350b. As will be appreciated by those of ordinary skill in the art, in other examples the first and second MOSFET devices 350a and 350b may be connected so that the direction of the body diode is reversed, in comparison with the example of FIG. 7, according to the structure of the gate driver for driving the switches.

In the example described above with reference to FIG. 4, the mode of operation of the switching transducer driver is controlled by adjusting a phase shift applied to a carrier wave that is supplied to the second comparator 414 of the PWM modulator circuitry 410. As will be appreciated by those of ordinary skill in the art, however, other approaches to controlling the mode of operation of a switching transducer are possible, e.g. using a self-oscillation modulator with coupled quantizers. Thus, it is to be appreciated that the PWM modulator circuitry 410 is only one example of a possible approach to controlling the mode of operation of the switching transducer driver of the present disclosure, and that alternative approaches could equally be employed.

In the example described above with reference to FIGS. 3-7, the Class D amplifier circuitry 300 is operable such that the output voltage across the load 330 may be equal to either a first voltage (which in the example described above with reference to FIG. 3 is a positive supply voltage +VDD) when the high-side switch 312 is switched on, a second voltage (which in the example described above with reference to FIG. 3 is a negative supply voltage −VDD) when the low-side switch 314 is switched on, or a fixed reference voltage (which in the example described above with reference to FIG. 3 is 0V) when the third switch 350 is switched on.

As will be appreciated by those of ordinary skill in the art, the energy lost in switching of the switches 312, 314, 350 of the Class D amplifier circuitry 300 is proportional to the switching frequency, the capacitance of the switch 312, 314, 350 that is switching, and the square of the voltage being switched by the relevant one of the switches 312, 314, 350.

In an alternative example, instead of a fixed reference voltage, the third switch may be coupled to a controllable voltage supply which supplies a voltage having a magnitude that can vary based on an input signal to the switching transducer driver circuitry. By adjusting the voltage of the controllable voltage supply based on the input signal, the voltage being switched can be set to a minimum required level, thus leading to reduced switching losses in comparison to the example described above with reference to FIGS. 3-7.

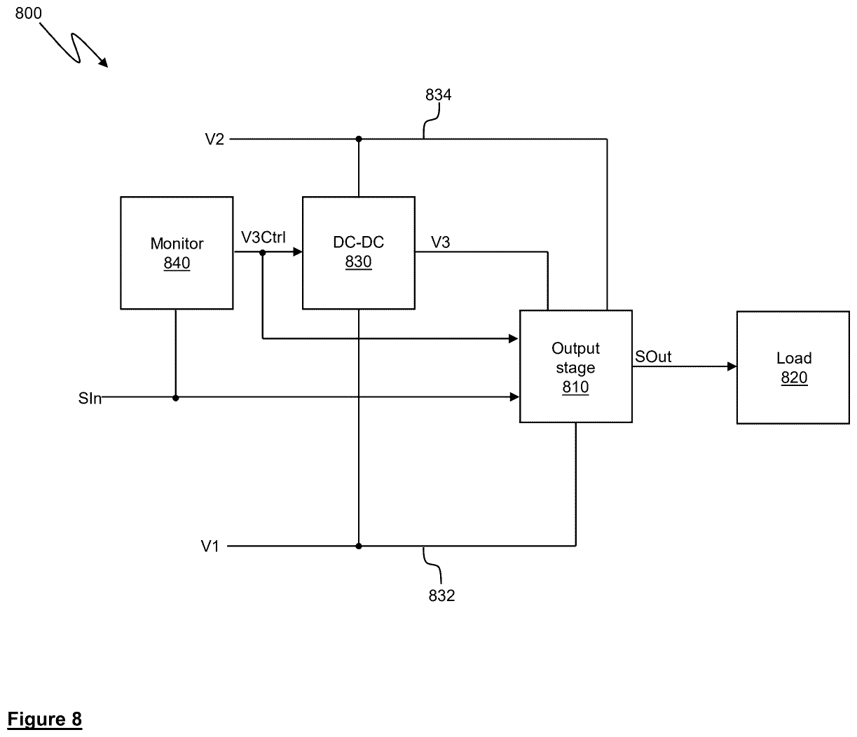

FIG. 8 is a schematic representation of alternative switching transducer driver circuitry according to the present disclosure.

The alternative switching transducer driver circuitry, shown generally at 800 in FIG. 8, comprises output stage circuitry 810 configured to receive an input signal SIn and to supply a drive signal Sout, based on the input signal SIn, to a load 820 such as an audio output transducer (e.g. a speaker). The output stage circuitry 810 may comprise modulator circuitry (e.g. pulse width modulator circuitry) and a full-bridge or half-bridge switching output stage. The output stage circuitry 810 may comprise, for example, Class D audio amplifier circuitry.

The switching transducer driver circuitry 800 further includes DC-DC converter circuitry 830 coupled to first and second supply voltage rails 832, 834 which supply respective first and second supply voltages V1, V2 to the DC-DC converter circuitry 830 and the output stage circuitry 810. The DC-DC converter circuitry 830 is configured to generate an output voltage V3 at a level between the first and second supply voltages V1, V2. The level of the output voltage V3 is controllable based on the input signal SIn, between a predefined minimum level and a predefined maximum level which may be equal to a mid-point voltage between the first and second supply voltages V1, V2, for example. Thus, if the first supply voltage V1 is equal to 0V and the second supply voltage V2 is equal to 48V, the predefined maximum level of the output voltage V3 of the DC-DC converter circuitry 830 may be 24V. The output voltage V3 is supplied to the output stage circuitry 810.

The DC-DC converter circuitry 830 may comprise inductive buck converter circuitry having a switch network and one or more inductors. The DC-DC converter circuitry 830 may be a zeta buck converter of a kind that will be familiar to those of ordinary skill in the art.

The switching transducer driver circuitry 800 further includes monitor circuitry 840 configured to monitor one or more parameters of the input signal SIn. The monitor circuitry 840 may be configured to monitor, for example, an instantaneous magnitude or an envelope of the input signal SIn, or a volume of an audio signal represented by the input signal SIn, or a volume control signal for or associated with such an audio signal.

The monitor circuitry 840 is further configured to determine a level of the output voltage V3 that should be supplied to the output stage circuitry 810, based on the monitored parameter(s) of the input signal SIn, and to output a control signal V3Ctrl indicative of the determined level of the output voltage V3 to the DC-DC converter circuitry 830, to cause the DC-DC converter circuitry 830 to adjust the level of the variable output voltage V3 accordingly, e.g. by adjusting a duty cycle of the DC-DC converter circuitry 830.

In examples in which the monitor circuitry 840 is operative to monitor the instantaneous magnitude of the input signal SIn, the level of the output voltage V3 can be controlled in real-time in response to a current magnitude of the input signal SIn.

In examples in which the monitor circuitry 840 is operative to monitor the envelope of the input signal SIn, the level of the output voltage V3 can be controlled based on long-term signal dynamics of the input signal SIn, while avoiding rapid fluctuations in the level of the output voltage V3 (as may occur in examples in which the variable output voltage V3 is controlled based on the instantaneous magnitude of the input signal SIn).

In examples in which the monitor circuitry 840 is operative to monitor the volume of (or a volume control signal for or associated with associated with) an audio signal represented by the input signal SIn, the peak signal level of the audio signal represented by the input signal SIn is known and the level of the output voltage V3 can be controlled accordingly to accommodate this peak signal level.

The monitor circuitry 840 may be further configured to output a signal indicative of the determined level of the output voltage V3 (e.g. the control signal V3Ctrl) to the output stage circuitry 810. Signalling the determined level of the output voltage V3 to the output stage circuitry 810 helps to ensure that switching sequences for the output stage circuitry 810 are generated correctly for the determined level of the controllable output voltage V3.

Alternatively, the output stage circuitry 810 may be configured to detect the determined output voltage V3. For example, control circuitry of the output stage circuitry 810 may be configured to detect or sense the output voltage V3 of the DC-DC converter circuitry 830. Again, knowledge of the determined output voltage V3 helps to ensure that switching sequences for the output stage circuitry 810 are generated correctly for the determined level of the controllable output voltage V3.

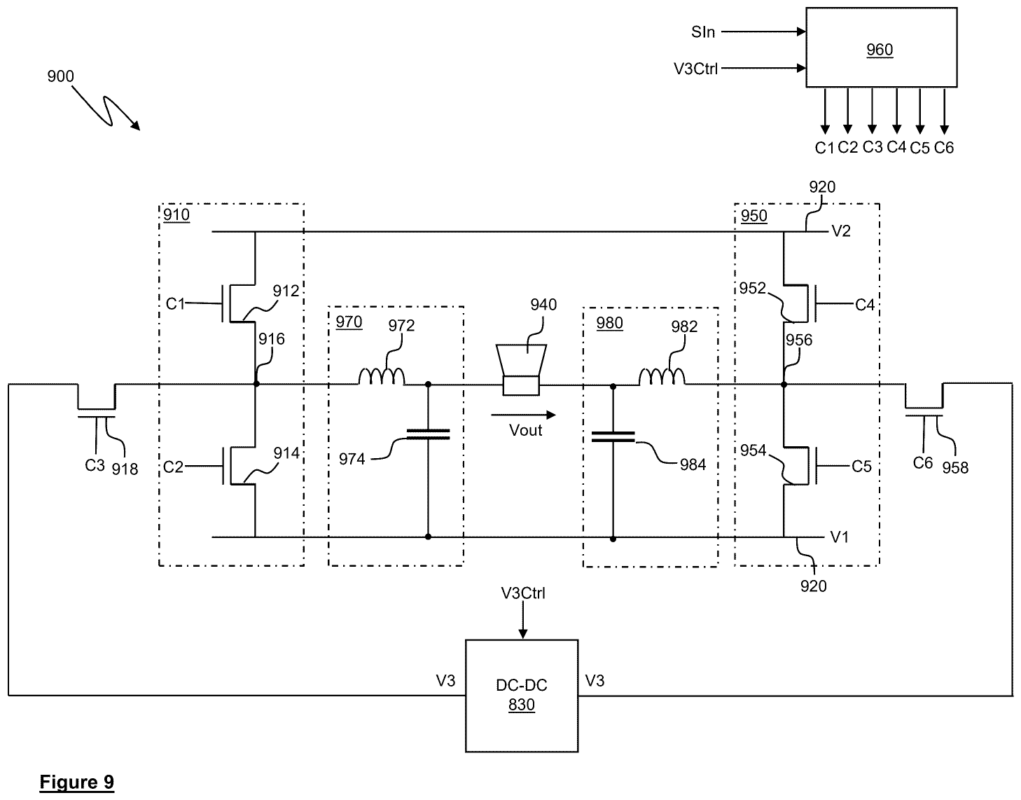

FIG. 9 is a schematic representation of an implementation of the switching transducer driver circuitry of FIG. 8 having a full-bridge output stage.

The switching transducer driver circuitry in this example is implemented as Class D amplifier circuitry, which is shown generally at 900 in FIG. 9.

The Class D amplifier circuitry 900 comprises a first half-bridge 910 comprising a first high-side switch 912 and a first low-side switch 914 coupled in series between a first power supply rail 920 that supplies the first supply voltage V1 (which may be, for example, a reference voltage supply rail coupled to a ground plane or other reference voltage supply) and a second power supply rail 930 that supplies the second supply voltage V2 (which may be a positive supply voltage +VDD, for example). An output node 916 of the first half-bridge 910 is coupled to a first terminal of a load 940.

The Class D amplifier circuitry 900 further comprises a second half-bridge 950 comprising a second high-side switch 952 and a second low-side switch 954 coupled in series between the first power supply rail 920 and the second power supply rail 930. An output node 956 of the second half-bridge 950 is coupled to a second terminal of the load 940.

The Class D amplifier circuitry 900 further comprises a first intermediate switch 918, having an input terminal coupled to the output of the DC-DC converter circuitry 830 to receive the output voltage V3 output by the DC-DC converter circuitry 830 and an output terminal coupled to the output node 916 of the first half-bridge 910.

The Class D amplifier circuitry 900 further comprises a second intermediate switch 958, having an input terminal coupled to the output of the DC-DC converter circuitry 830 to receive the output voltage V3 output by the DC-DC converter circuitry 830 and an output terminal coupled to the output node 956 of the second half-bridge 950.

The Class D amplifier circuitry 900 of FIG. 9 may be configured for operation with relatively high output power. For example, the first supply voltage V1 may be positive power supply voltage +VDD having a magnitude of 50V DC or more. The first and second high-side switches 912, 952 and the first and second low-side switches 914, 954 may thus be configured for operation at such voltages. In some examples the first and second high-side switches 912, 952 and the first and second low-side switches 914, 954 may be wide bandgap devices or high electron mobility transistor (HEMT) devices based on, for example, Gallium Nitride (GaN), Silicon Carbide (SIC), Gallium Oxide (Ga203) or other semiconductor materials. Such devices are typically capable of operation at higher voltages, higher temperatures and higher frequencies than silicon-based switches such as MOSFETs, and so for high power applications (e.g. applications in which the supply voltage magnitude is equal to or greater than 50V DC) may provide a more cost effective solution than silicon-based devices. The first and second intermediate switches 918, 958 may also be wide bandgap devices or high electron mobility transistor (HEMT) devices based on, for example, Gallium Nitride (GaN), Silicon Carbide (SiC), Gallium Oxide (Ga₂0₃) or other semiconductor materials, or alternatively may be MOSFET devices.

The Class D amplifier circuitry 900 further comprises control circuitry 960 configured to control operation of the Class D amplifier circuitry 900. The control circuitry 960 may comprise modulator circuitry, e.g. pulse width modulator circuitry. The control circuitry 960 receives the input signal SIn. The control circuitry 960 may also receive a signal (e.g. the control signal V3Ctrl) indicative of the determined level of the output voltage V3 output by the DC-DC converter circuitry 830, or may be configured to detect or sense the output voltage V3 of the DC-DC converter circuitry 830. The control circuitry 960 may also be configured to detect or sense the levels of the first and second supply voltages V1, V2 (or may otherwise be provided with the levels of the first and second supply voltages V1, V2) and may thus be able to determine the level of the output voltage V3 relative to the first and second supply voltages V1, V2.

The control circuitry 960 is operative to generate control signals C1, C2, C3, C4, C5 and C6 for controlling the first high-side switch 912, the first low-side switch 914, the first intermediate switch 918, the second high-side switch 952, the second low-side switch 954 and the second intermediate switch 958, respectively, based on the input signal SIn and the output voltage V3 of the DC-DC converter circuitry 830.

In use of the Class D amplifier circuitry 900, control signals C1-C6 are supplied by the control circuitry 960 to control terminals of the first high-side switch 912, the first low-side switch 914, the first intermediate switch 918, the second high-side switch 952, the second low-side switch 954 and the second intermediate switch 958 respectively. The control signals C1-C6 are arranged such that only one switch on each side of the load 940 can be switched on at a time.

For example, when control signals C1-C6 are output by the control circuitry 960 to switch the first high-side switch 912 and the second low-side switch 954 on, an output voltage Vout equal to V2-V1 develops across the load 940. When control signals C1-C6 are output by the control circuitry 960 to switch the first intermediate switch 918 and the second low-side switch 954 on, an output voltage Vout equal to V3−V1 develops across the load 940. When control signals C1-C6 are output by the control circuitry 960 to switch the first high-side switch 912 and the second intermediate switch 958 on, an output voltage Vout equal to V2-V3 develops across the load 940.

When control signals C1-C6 are output by the control circuitry 960 to switch the second high-side switch 952 and the first low-side switch 914 on, an output voltage Vout equal to V1−V2 develops across the load 940. When control signals C1-C6 are output by the control circuitry 960 to switch the second intermediate switch 958 and the first low-side switch 914 on, an output voltage equal to V1−V3 develops across the load 940. When suitable control signals C1-C6 are output by the control circuitry 960 to switch the second high-side switch 952 and the first intermediate switch 918 on, an output voltage equal to V3−V2 develops across the load 940.

When control signals C1-C6 are output by the control circuitry 960 to switch the first low-side switch 914 and the second low-side switch 954 on, an output voltage Vout equal to V1−V1=0V develops across the load 940.

In use of the Class D amplifier circuitry 900, at idle (i.e. when no input signal SIn is present), the first and second low-side switches 914, 954 are switched on and the first and second high-side switches 912, 952 and the first and second intermediate switches 918, 958 are switched off, such that an output voltage of 0V develops across the load 940.

At low input signal levels, e.g. input signal levels for which an output power requirement can be satisfied by supplying a voltage at a level equal to or less than the predefined maximum level of the output voltage V3 of the DC-DC converter circuitry 830 to the load 940 (e.g. where the monitored parameter of the input signal SIn is below a predefined input signal threshold), the control circuitry 960 is operative to control the first and second low-side switches 914, 954 and the first and second intermediate switches 918, 958 such that the voltage across the load 940 switches between V3−V1, V1−V3 and 0V according to the input signal SIn. The DC-DC converter circuitry 830 controls the level of its output voltage V3 between the predefined minimum level and the predefined maximum level according to the monitored parameter of the input signal SIn, to ensure that the voltage being switched by the switches 914, 954, 918, 958 is as low as possible while still supplying the required output power. In this way, switching losses can be minimised.

At high input signal levels, e.g. input signal levels for which the output power requirement cannot be satisfied by supplying a voltage at a level equal to or less than the predefined maximum level of the output voltage V3 of the DC-DC converter circuitry 830 to the load 940 (e.g. where the monitored parameter of the input signal SIn is equal to or greater than the predefined input signal threshold), the control circuitry 960 is operative to control the first and second high-side switches 912, 952, the first and second low-side switches 914, 954 and the first and second intermediate switches 918, 958 such that the voltage across the load 940 switches between V3 and V2 on one side of the load 940 and between V3 and V1 on the other side of the load 940, according to the input signal SIn, to permit a maximum voltage swing across the load to ensure that the required output power can be supplied by the Class D amplifier circuitry 900, while also minimising the voltage being switched by the switches 912, 914, 918, 952, 954, 958 to minimise switching losses.

By adjusting the output voltage V3 of the DC-DC converter circuitry 830 based on the input signal SIn, and also controlling the switches 912, 914, 918, 952, 954, 958 in this way, an improved balance between switching loss, power efficiency and output signal fidelity can be achieved, in comparison to the example described above with reference to FIGS. 3-7.

in this example illustrated in FIG. 9, the Class D amplifier circuitry 900 includes first low-pass filter circuitry 970 between the first half-bridge 910 and the load 940 and second low-pass filter circuitry 980 between the second half-bridge 980 and the load 940. The first low-pass filter circuitry 970 comprises an inductor 972 coupled between the output node 916 of the first half-bridge 910 and the first terminal of the load 940 and a capacitor 974 coupled between the first terminal of the load 940 and the first power supply rail 920. Similarly, the second low-pass filter circuitry 980 comprises an inductor 982 coupled between the output node 956 of the second half-bridge 950 and the second terminal of the load 940 and a capacitor coupled between the second terminal of the load 940 and the first power supply rail 920. The first and second low-pass filter circuitry 970, 980 are configured to attenuate high frequency components that may be present in output signals of the first and second half-bridges 910, 950, respectively, due to the switching frequency of the switches 912, 914, 952, 954.

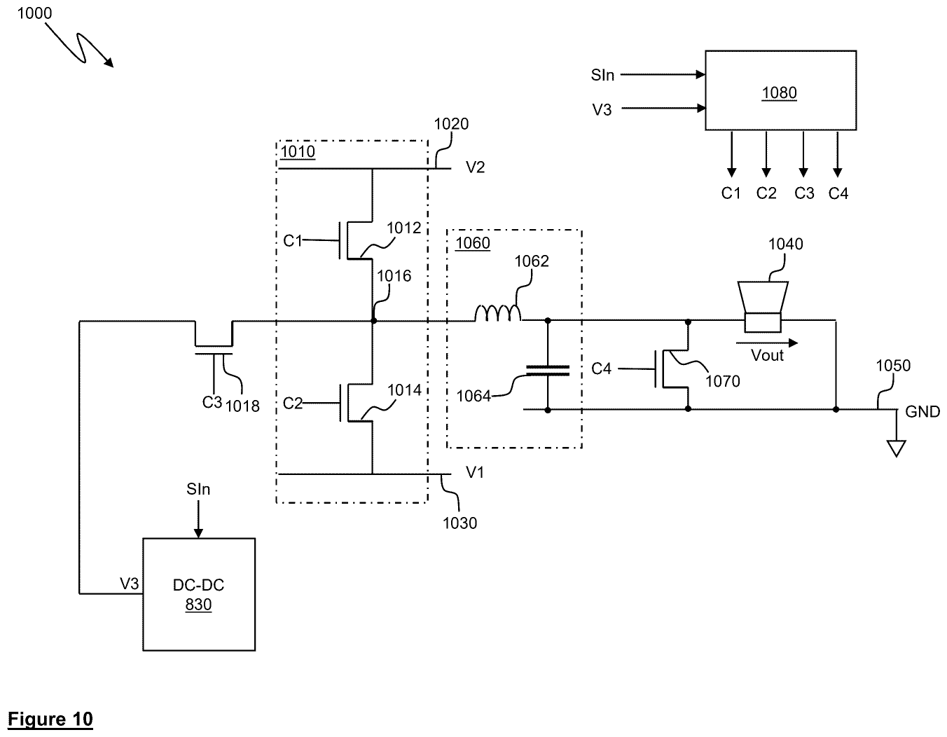

FIG. 10 is a schematic representation of an implementation of the switching transducer driver circuitry of FIG. 8 having a half-bridge output stage.

The switching transducer driver circuitry in this example is implemented as Class D amplifier circuitry, which is shown generally at 1000 in FIG. 10.

The Class D amplifier circuitry 1000 comprises a half-bridge 1010 comprising a high-side switch 1012 and a low-side switch 1014 coupled in series between a first power supply rail 1020 that supplies the first supply voltage V1 (which may be, for example, a negative supply voltage −VDD) and a second power supply rail 1030 that supplies the second supply voltage V2 (which may be a positive supply voltage +VDD, for example). An output node 1016 of the half-bridge 1010 is coupled to a first terminal of a load 1040 (in this example via low-pass filter circuitry, described below). A second terminal of the load 1040 is coupled to a reference voltage supply rail 1050 which is coupled to a ground plane or other reference voltage supply.

The Class D amplifier circuitry 1000 further comprises an intermediate switch 1018, having an input terminal coupled to the output of the DC-DC converter circuitry 830 to receive the output voltage V3 output by the DC-DC converter circuitry 830 and an output terminal coupled to the output node 1016 of the half-bridge 1010.

The Class D amplifier circuitry 1000 may further comprise low-pass filter circuitry 1060 configured to attenuate high-frequency components that may be present in an output signal of the half-bridge 1010. The low-pass filter circuitry 1060 in this example comprises an inductor 1062 coupled between the output node 1016 of the half-bridge 1010 and the first terminal of the load 1040 and a capacitor coupled between the first terminal of the load 1040 and the reference voltage supply rail 1050. The Class D amplifier circuitry 1000 may further comprise a fourth switch 1070 coupled between the first terminal of the load 1040 and the reference voltage supply rail 1050.

The Class D amplifier circuitry 1000 of FIG. 10 may be configured for operation with relatively high output power. For example, the first and second supply voltages V1, V2 may be respective negative and positive power supply voltages-VDD, +VDD, each having a magnitude of 50V DC or more. The high-side switch 1012 and the low-side switch 1014 may thus be configured for operation at such voltages. In some examples the high-side switch 1012 and the low-side switch 1014 may be wide bandgap devices or high electron mobility transistor (HEMT) devices based on, for example, Gallium Nitride (GaN), Silicon Carbide (SiC), Gallium Oxide (Ga203) or other semiconductor materials. The intermediate switches 1018 and the fourth switch 1070 (if present) may also be wide bandgap devices or high electron mobility transistor (HEMT) devices based on, for example, Gallium Nitride (GaN), Silicon Carbide (SIC), Gallium Oxide (Ga₂0₃) or other semiconductor materials, or alternatively may be MOSFET devices.

The Class D amplifier circuitry 1000 further comprises control circuitry 1080 configured to control operation of the Class D amplifier circuitry 1000. The control circuitry 1060 may comprise modulator circuitry, e.g. pulse width modulator circuitry. The control circuitry 1080 receives the input signal SIn. The control circuitry 1080 may also receive a signal (e.g. the control signal V3Ctrl) indicative of the determined level of the output voltage V3 output by the DC-DC converter circuitry 830, or may be configured to detect or sense the output voltage V3 of the DC-DC converter circuitry 830. The control circuitry 1080 may also be configured to detect or sense the levels of the first and second supply voltages V1, V2 (or may otherwise be provided with the levels of the first and second supply voltages V1, V2) and may thus be able to determine the level of the output voltage V3 relative to the first and second supply voltages V1, V2.

The control circuitry 1080 is operative to generate control signals C1, C2, C3 and C4 for controlling the high-side switch 1012, the low-side switch 1014, the intermediate switch 1018 and the fourth switch 1070 (if present), based on the input signal SIn and the output voltage V3 of the DC-DC converter circuitry 830.

In use of the Class D amplifier circuitry 1000, control signals C1-C4 are supplied by the control circuitry 1080 to control terminals of the high-side switch 1012, the low-side switch 1014, the intermediate switch 1018 and the fourth switch 1070. The control signals C1-C4 are arranged such that only one of the high-side switch 1012, the low-side switch 1014, the intermediate switch 1018 and the fourth switch 1070 can be switched on at a time.

For example, when control signals C1-C4 are output by the control circuitry 1080 to switch the high-side switch 1012 on, an output voltage Vout equal to V2 develops across the load 1040.

When control signals C1-C4 are output by the control circuitry 1080 to switch the intermediate switch 1018 on, an output voltage Vout equal to V3 develops across the load 1040.

When control signals C1-C4 are output by the control circuitry 1080 to switch, the low-side switch 1014 is on, an output voltage Vout equal to V1 develops across the load 1040.

When control signals C1-C4 are output by the control circuitry 1080 to switch the fourth switch 1070 on, both terminals of the load are coupled to the reference voltage supply rail 1050 and no voltage develops across the load 1040.

In use of the Class D amplifier circuitry 1000, at idle (i.e. when no input signal SIn is present), the fourth switch 1070 is switched on and the high-side switch 1012, low-side switch 1014 and intermediate switch 1018 are switched off, such that no output voltage develops across the load 1040.

At low input signal levels, e.g. input signal levels for which an output power requirement can be satisfied by supplying a voltage at a level equal to or less than the predefined maximum level of the output voltage V3 of the DC-DC converter circuitry 830 to the load 1040 (e.g. where the monitored parameter of the input signal SIn is below a predefined input signal threshold), the control circuitry 1080 is operative to control the low-side switch 1014 and the intermediate switch 1018 such that the voltage across the load 1040 switches between V1 and V3 according to the input signal Sin. The DC-DC converter circuitry 830 controls the level of its output voltage V3 between the predefined minimum level and the predefined maximum level according to the monitored parameter of the input signal SIn, to ensure that the voltage being switched by the switches 1014, 1018 is as low as possible while still supplying the required output power. In this way, switching losses can be minimised.

At high input signal levels, e.g. input signal levels for which the output power requirement cannot be satisfied by supplying a voltage at a level equal to or less than the predefined maximum level of the output voltage V3 of the DC-DC converter circuitry 830 to the load 1040 (e.g. where the monitored parameter of the input signal SIn is equal to or greater than the predefined input signal threshold), the control circuitry 1080 is operative to control the high-side switch 1012 and the low-side switch 1014 such that the voltage across the load 1040 switches between V2 and V3, according to the input signal Sin, to ensure that the required output power can be supplied by the Class D amplifier circuitry 1000, while also minimising the voltage being switched by the switches 1012, 1014 to minimise switching losses.

By adjusting the output voltage V3 of the DC-DC converter circuitry 830 based on the input signal SIn, and also controlling the switches 1012, 1014, 1018, 1070, an improved balance between switching loss, power efficiency and output fidelity can be achieved, in comparison to the example described above with reference to FIGS. 3-7.

As noted above, the monitor circuitry 840 is configured to determine a level of the output voltage V3 that should be supplied to the output stage circuitry 810, based on the monitored parameter(s) of the input signal SIn.

In a first approach, the monitor circuitry 840 may be operative to determine the level of the output voltage V3 of the DC-DC converter circuitry 830 for a given amplitude A of the output signal Vout based on the relationship V3(A)=min (A, V/2), where V/2 is the mid-point voltage between the first and second supply voltages V1, V2. Thus, in the first approach the monitor circuitry 840 is operative to determine the level of the output voltage V3 of the DC-DC converter circuitry 830 as a minimum of the magnitude A of the output signal Vout and a mid-point voltage level between a level of the first supply voltage and a level of the second supply voltage.

In such an arrangement, for small and mid-level signals, the output voltage V3 of the DC-DC converter circuitry 830 is equal to the amplitude A of the output signal Vout, while for larger signals, the output voltage V3 of the DC-DC converter circuitry 830 is capped at the mid-point voltage between the first and second supply voltages V1, V2.

This is a simple way of determining the output voltage V3 of the DC-DC converter circuitry 830 which maintains the output voltage V3 at a safe level, while reducing switching losses across the full dynamic range of the output signal Vout.

In a second approach, the monitor circuitry may be configured to determine the level of the output voltage V3 of the DC-DC converter circuitry 830 for a given amplitude A of the output signal Vout based on the relationships V3(A)=A if A≤0.4506V and

$$V 3 ( A ) = \frac{V}{2} ( 0.5 + 0.5 \sqrt{\frac{A}{V}} ) if A > 0.4 \; 506 V .$$

This is a marginally more complex way of determining the output voltage V3 of the DC-DC converter circuitry 830 than the first approach described above, but provides a greater reduction in switching losses than the first approach.

The switching transducer driver circuitry of FIGS. 8, 9 and 10 may be implemented in a variety of ways.

In some examples, the switches of the output stage circuitry (i.e. the first and second high-side switches 912, 952, the first and second low-side switches 914, 954 and the first and second intermediate switches 918, 958 in the FIG. 9 example, or the high-side switch 1012, the low-side switch 1014, the intermediate switch 1018 and the fourth switch 1070 in the FIG. 10 example) are integrated with the switches of the switch network of the DC-DC converter circuitry 830 in a single integrated circuit (IC). In such examples, the inductor(s) of the DC-DC converter circuitry 830 may be integrated with the switches in the single IC (i.e. the inductor(s) may be on-chip), or may alternatively be provided externally of the single IC (i.e. the inductor(s) may be off-chip), and the single IC may be provided with suitable coupling nodes for coupling to the off-chip inductor(s). Such an implementation may be referred to as a combined output stage and DC-DC converter IC.

In such a combined output stage and DC-DC converter IC implementation, all the switches (i.e. all the switches of the output stage circuitry 810 and all the switches of the DC-DC converter circuitry 830) may be implemented using wide bandgap devices or high electron mobility transistor (HEMT) devices based on, for example, Gallium Nitride (GaN), Silicon Carbide (SiC), Gallium Oxide (Ga₂0₃) or other semiconductor materials.

In other examples, the switches of the switch network of the DC-DC converter circuitry 830 and the high-side and low-side switches of the output stage circuitry 810 may be may be wide bandgap devices or high electron mobility transistor (HEMT) devices based on, for example, Gallium Nitride (GaN), Silicon Carbide (SIC), Gallium Oxide (Ga₂0₃) or other semiconductor materials and the intermediate switches of the output stage circuitry 810 may be implemented using one or more MOSFET devices or one or more wide-bandgap or HEMT devices based on a different semiconductor material, e.g. SiN. In such examples, all the switches may be integrated in a single integrated circuit with on-chip or off-chip inductor(s) for the DC-DC converter circuitry, or alternatively the switches of the switch network of the DC-DC converter circuitry 830 and the high-side and low-side switches of the output stage circuitry 810 may be integrated in a first IC and the intermediate switches of the output stage circuitry 810 may be integrated in a second IC.

In still other examples, the high-side and low-side switches of the output stage circuitry 810 may be may be wide bandgap devices or high electron mobility transistor (HEMT) devices based on, for example, Gallium Nitride (GaN), Silicon Carbide (SiC), Gallium Oxide (Ga203) or other semiconductor materials and the intermediate switches of the output stage circuitry 810 and the switches of the switch network of the DC-DC converter circuitry may be implemented using one or more MOSFET devices or one or more wide-bandgap or HEMT devices based on a different semiconductor material, e.g. SiN. In such examples, all the switches may be integrated in a single integrated circuit with on-chip or off-chip inductor(s) for the DC-DC converter circuitry, or alternatively the high-side and low-side switches of the output stage circuitry 810 may be integrated in a first IC and the intermediate switches of the output stage circuitry 810 and the switches of the switch network of the DC-DC converter circuitry 830 and may be integrated in a second IC.

The circuitry described above with reference to the accompanying drawings may be incorporated in a host device such as a vehicle, a laptop, notebook, netbook or tablet computer, an automotive system, e.g. as an audio system for a vehicle, a gaming device such as a games console or a controller for a games console, a virtual reality (VR) or augmented reality (AR) device, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog™ or VHDL (Very high speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. Switching transducer driver circuitry for driving a load, the switching transducer driver circuitry comprising:
output stage circuitry comprising:
a first output stage switch operable to couple the load to a first voltage supply;
a second output stage switch operable to couple the load to a second voltage supply; and
a third output stage switch operable to couple the load to a controllable third voltage supply,
wherein a voltage level of the controllable third voltage supply is based on an input signal to the switching amplifier circuitry.

2. The switching transducer driver circuitry of claim 1, further comprising DC-DC converter circuitry configured to provide the controllable third voltage supply.

3. The switching transducer driver circuitry of claim 1, further comprising monitor circuitry configured to:
monitor a parameter of the input signal;
determine a desired voltage level of the controllable third voltage supply based on the monitored parameter of the input signal; and
output a signal indicative of the desired voltage level of the controllable third voltage supply to DC-DC converter circuitry coupled to the switching transducer driver circuitry.

4. The switching transducer driver circuitry of claim 3, wherein the monitor circuitry is configured to monitor one or more of:
an instantaneous magnitude of the input signal;
an envelope of the input signal; and
a volume control signal associated with the input signal.

5. The switching transducer circuitry of claim 1, wherein the output stage circuitry comprises control circuitry for controlling operation of the first, second and third output stage switches based on the input signal and the voltage level of the controllable third voltage supply.

6. The switching transducer driver circuitry of claim 5, wherein the control circuitry is configured to detect the voltage level of the controllable third voltage supply.

7. The switching transducer driver circuitry of claim 3, wherein the output stage circuitry comprises control circuitry for controlling operation of the first, second and third output stage switches based on the input signal and the voltage level of the controllable third voltage supply, and wherein the monitor circuitry is configured to output a signal indicative of the desired voltage level of the controllable third voltage supply to the control circuitry.

8. The switching transducer driver circuitry of claim 1, wherein a maximum voltage level of the controllable third voltage supply is equal to a mid-point voltage level between a level of the first supply voltage and a level of the second supply voltage.

9. The switching transducer driver circuitry of claim 3, wherein the monitor circuitry is configured to determine the desired voltage level of the controllable third voltage supply for a given magnitude A of an output signal of the switching transducer driver circuitry as a minimum of the magnitude A of the output signal and a mid-point voltage level between a level of the first supply voltage and a level of the second supply voltage.

10. The switching transducer driver circuitry of claim 3, wherein the monitor circuitry is configured to determine the desired level of the controllable third voltage supply for a given magnitude A of an output signal of the switching transducer driver circuitry as:
the magnitude A of the output signal, if A is equal to or less than a predefined output signal magnitude threshold; or
(0.5+0.5√(A/V)), if A is greater than the predefined output signal magnitude threshold, where V is equal to a difference between a level of the first voltage supply and a level of the second voltage supply.

11. The switching transducer driver circuitry of claim 1, wherein the first and second output stage switches are implemented using wide bandgap or high electron mobility transistor (HEMT) devices.

12. The switching transducer driver circuitry of claim 11, wherein the third output stage switch is implemented using a wide bandgap or high electron mobility transistor (HEMT) device.

13. The switching transducer driver circuitry of claim 2, wherein the DC-DC converter circuitry comprises zeta buck converter circuitry.

14. A combined output stage and DC-DC converter integrated circuit (IC), the combined output stage and DC-DC converter IC comprising:
a switch network for a DC-DC converter;
a first output stage switch operable to couple a load to a first voltage supply;
a second output stage switch operable to couple the load to a second voltage supply; and
a third output stage switch operable to couple the load to a controllable third voltage supply,
wherein the controllable third voltage supply is supplied by the DC-DC converter.

15. The combined output stage and DC-DC converter IC of claim 14, further comprising an inductor for the DC-DC converter.

16. The combined output stage and DC-DC converter IC of claim 14, wherein the first and second output stage switches and switches of the switch network for the DC-DC converter are implemented using wide bandgap or high electron mobility transistor (HEMT) devices.

17. The combined output stage and DC-DC converter IC of claim 16, wherein the third output stage switch is implemented using a wide bandgap or high electron mobility transistor (HEMT) device.

18. A host device comprising the switching transducer driver circuitry of claim 1.

19. The host device of claim 18, wherein the host device comprises a vehicle, a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console, a VR or AR device, a mobile telephone, a portable audio player or other portable device.
